(19) United States
(12) Patent Application Publication
(10) Pub. No.: US 2026/0026022 A1
(43) Pub. Date: Jan. 22, 2026

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Yohei YUDA, Tokyo (JP); Tatsuro WATAHIKI, Tokyo (JP)

(73) Assignee: Mitsubishi Electric Corporation, Tokyo (JP)

(21) Appl. No.: 18/997,998

(22) PCT Filed: Aug. 3, 2022
(86) PCT No.: PCT/JP2022/029781

§ 371 Date: Jan. 23, 2025

(51) Int. Cl. H10D 8/60; H10D 8/00; H10D 8/01; H10D 62/10; H10D 62/82; H10D 64/00

(52) U.S. Cl. CPC H10D 8/60; H10D 8/411; H10D 62/103; H10D 62/8271; H10D 8/045; H10D 8/051; H10D 64/111

(57) ABSTRACT

A leakage current is suppressed. A semiconductor device includes: a first anode electrode formed in a part of an upper surface of a gallium oxide layer of a first conductivity type; a semiconductor layer of a second conductivity type to cover a part of the gallium oxide layer and at least a part of the first anode electrode; and a second anode electrode to cover the semiconductor layer, wherein a plurality of trenches is formed in a surface layer of the gallium oxide layer, the first anode electrode is formed in the surface layer of the gallium oxide layer, the first anode electrode not overlapping the trenches in a plan view, and the semiconductor layer covers the gallium oxide layer in an inner portion of the trenches.

### TECHNICAL FIELD

The technology disclosed in this DESCRIPTION relates to a semiconductor technology.

### BACKGROUND ART

Power electronics (abbreviated as PE) is a technology for promptly and efficiently converting, for example, a direct current, an alternating current, or a frequency of electricity. PE (technology) is a mixture technology of not only the conventional power engineering but also the electronic engineering and the control engineering which are based on recent semiconductors. Today, such PE is applied to everywhere where electricity is used, for example, for power, industry, and transportation, and further for home.

Recent years have seen continuing upward trends in rate of electric energy to total energy consumption, that is, rate of electrification not only in Japan but also on a worldwide basis. As a background to this trend, convenient and energy-saving equipment in terms of electricity usage has been developed. This increases the utilization ratio of electricity. The PE technology is a base technology of these.

The PE technology is also a technology for converting an input into an electric state appropriate for equipment to be used, whatever the electric state (e.g., the magnitude of a frequency, a current, or a voltage) to be converted is. The base elements in the PE technology are rectifiers and inverters. Furthermore, semiconductors and semiconductor elements such as diodes and transistors which are applications of the semiconductors place the foundations of the rectifiers and the inverters.

In today's PE fields, diodes serving as semiconductor rectifying elements are used for various purposes including electrical equipment. The diodes are applied in wide frequency bands.

In recent years, switching elements capable of operating with low losses and at high frequencies in applications that require a high breakdown voltage and a high capacity have been developed and put to practical use. Also, materials contained in the switching elements have shifted to wide-gap materials to increase the breakdown voltages of the elements. Example representative elements aiming at increasing the breakdown voltages include Schottky barrier diodes (i.e., SBDs) and p-n diodes (PNDs). These diodes are widely used in various applications.

Trench MOS-type SBDs have been developed as elements each including a semiconductor layer made of gallium oxide as exemplified in, for example, Patent Document 1. When a reverse voltage is applied to an SBD containing a semiconductor material with high breakdown strength, a leakage current between an anode electrode and a semiconductor material layer typically increases. In contrast, in the trench MOS-type SBD of which example is described in Patent Document 1, the electric field applied to an edge portion of an anode electrode can be dispersed and reduced. This can improve the reverse breakdown voltage of the element.

Next, a trench-type junction barrier controlled Schottky diode (JBS) as exemplified in, for example, Patent Document 2 includes an depletion layer. When a reverse voltage is applied to the diode, the depletion layer extends from a p-type semiconductor layer to an n-type semiconductor layer that is a protrusion. Then, closing a channel produces an advantage of suppressing the leakage current.

### PRIOR ART DOCUMENT

### Patent Document

Patent Document 1: Japanese Unexamined Patent Application Publication No. 2020-170787

Patent Document 2: Japanese Unexamined Patent Application Publication No. 2019-036593

### SUMMARY

### Problem to be Solved by the Invention

It is likely that the MOS-type SBD exemplified in Patent Document 1 is less effective at suppressing the leakage current than that of the JBS structure exemplified in Patent Document 2 using the p-type semiconductor. In contrast, the structure exemplified in Patent Document 2 has difficulty in forming a p-n junction.

The technology disclosed in this DESCRIPTION has been conceived in view of the problems, and is a technology for suppressing the leakage current.

### Means to Solve the Problem

A semiconductor device according to the first aspect of the technology disclosed in DESCRIPTION includes: a gallium oxide layer of a first conductivity type; a first anode electrode formed in a part of an upper surface of the gallium oxide layer; a semiconductor layer of a second conductivity type to cover a part of the gallium oxide layer and at least a part of the first anode electrode; and a second anode electrode to cover the semiconductor layer, wherein a plurality of trenches is formed in a surface layer of the gallium oxide layer, the first anode electrode is formed in the surface layer of the gallium oxide layer, the first anode electrode not overlapping the trenches in a plan view, and the semiconductor layer covers the gallium oxide layer in an inner portion of the trenches.

### Effects of the Invention

At least the first aspect of the technology disclosed in DESCRIPTION can suppress the leakage current.

The object, features, aspects, and advantages relating to the technology disclosed in DESCRIPTION will become more apparent from the following detailed description and the accompanying drawings.

### BRIEF DESCRIPTION OF DRAWINGS

FIG. 1 is a cross-sectional view schematically illustrating an example structure of a semiconductor device according to an embodiment.

FIG. 2 is a cross-sectional view illustrating a method for manufacturing the semiconductor device according to the embodiment.

FIG. 3 is a cross-sectional view illustrating the method for manufacturing the semiconductor device according to the embodiment.

FIG. 4 is a cross-sectional view illustrating the method for manufacturing the semiconductor device according to the embodiment.

FIG. 5 is a cross-sectional view illustrating the method for manufacturing the semiconductor device according to the embodiment,

FIG. 6 is a cross-sectional view illustrating the method for manufacturing the semiconductor device according to the embodiment.

FIG. 7 is a cross-sectional view illustrating the method for manufacturing the semiconductor device according to the embodiment.

FIG. 8 is a cross-sectional view illustrating the method for manufacturing the semiconductor device according to the embodiment.

FIG. 9 is a cross-sectional view schematically illustrating an. example structure of a semiconductor device according to an embodiment.

FIG. 10 is a cross-sectional view illustrating a method for manufacturing the semiconductor device according to the embodiment.

FIG. 11 is a cross-sectional view illustrating the method for manufacturing the semiconductor device according to the embodiment.

FIG. 12 is a cross-sectional view schematically exemplifying a structure of a semiconductor device according to an embodiment.

FIG. 13 is a cross-sectional view illustrating a method for manufacturing the semiconductor device according to the embodiment.

FIG. 14 is a cross-sectional view illustrating a method for manufacturing the semiconductor device according to the embodiment.

### DESCRIPTION OF EMBODIMENTS

Embodiments will be hereafter described with reference to the attached drawings. Although detailed features are described in Embodiments below for description of the technology, they are mere exemplification and not necessarily essential features for making Embodiments feasible.

Note that the drawings are drawn in schematic form, and structures are appropriately omitted or simplified for convenience of description. The mutual relationships in size and position between the structures in the different drawings are not necessarily accurate but may be appropriately changed. The drawings such as plan views except cross-sectional views are sometimes hatched for facilitating the understanding of the details of Embodiments.

In the following description, the same reference numerals are assigned to the same constituent elements, and their names and functions are the same. Therefore, detailed description of such constituent elements may be omitted to avoid redundant description.

Unless otherwise specified, an expression “comprising”, “including”, or “having” a certain constituent element is not an exclusive expression for excluding the presence of the other constituent elements in this DESCRIPTION.

Even when the ordinal numbers such as “first” and “second” are used in the following description, these terms are used for convenience to facilitate the understanding of the details of Embodiments. The order indicated by these ordinal numbers does not restrict the details of Embodiments.

In DESCRIPTION, even when terms expressing a particular position and a particular direction such as “up”, “down”, “left”, “right”, “side”, “bottom”, “front”, or “back” are used, these terms are used for convenience to facilitate the understanding of the details of Embodiments, and do not relate to positions or directions in which Embodiments are actually implemented.

In DESCRIPTION, the expression of, for example, “an upper surface of” or “a lower surface of” a target element includes states where not only the upper surface or the lower surface of the element itself is formed but also another element is formed on the upper surface or the lower surface of the target element. Specifically, for example, the expression “B formed on the upper surface of A” does not prevent interposition of another element “C” between A and B.

### Embodiment 1

An oxide semiconductor device as a semiconductor device according to Embodiment 1, and a method for manufacturing the oxide semiconductor device will be described. First, a structure of the oxide semiconductor device according to Embodiment 1 will be described. In the following description, the oxide semiconductor device may be simply referred to as a “semiconductor device”.

### Structure of Semiconductor Device

The semiconductor device according to Embodiment 1 will be described using an anode electrode as an electrode on an upper side of a substrate, and using a cathode electrode as an electrode on a lower side of the substrate. The semiconductor device according to Embodiment 1 is, however, not limited to an SBD but may be another power device element such as a switching element.

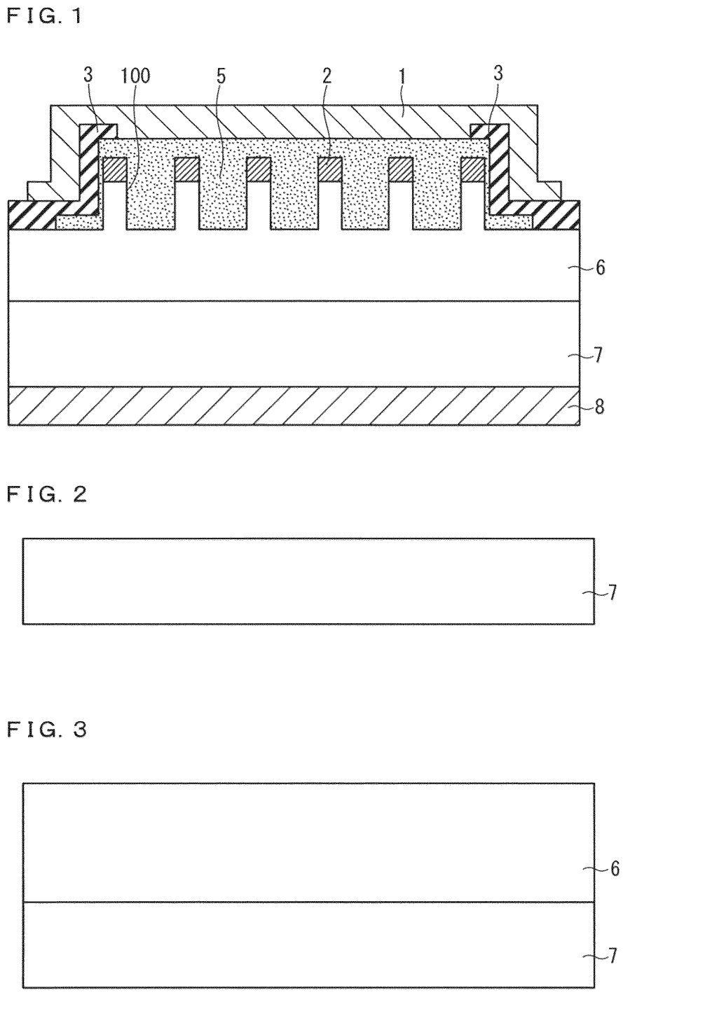

FIG. 1 is a cross-sectional view schematically illustrating an example structure of a semiconductor device according to Embodiment 1. As illustrated in the example of FIG. 1, the semiconductor device includes an n-type gallium oxide layer. Although the n-type gallium oxide layer including an n-type single-crystal gallium oxide substrate 7 and an n-type gallium oxide epitaxial layer 6 will be described, the n-type gallium oxide layer is not limited to this example structure.

The n-type single-crystal gallium oxide substrate 7 is an n-type oxide semiconductor including an upper surface (a first main surface) and a lower surface opposite to the upper surface (a second main surface). The n-type gallium oxide epitaxial layer 6 is an epitaxial layer formed on the upper surface of the n-type single-crystal gallium oxide substrate 7.

The semiconductor device exemplified in FIG. 1 includes a trench structure 100 in a surface layer of the n-type gallium oxide epitaxial layer 6, in an active region enclosed by a termination structure in a plan view. The semiconductor device includes anode electrodes 2 each of which is an electrode that forms an electrical Schottky junction with the n-type gallium oxide epitaxial layer 6.

The semiconductor device includes a p-type semiconductor layer 5 formed to cover an inner portion and an external portion of the trench structure 100. The p-type semiconductor layer 5 is made of a material containing an element different from gallium oxide as a main component, and forms a hetero p-n junction with the n-type gallium oxide epitaxial layer 6.

Furthermore, the semiconductor device exemplified in FIG. 1 includes, in the termination structure formed outside of the active region in which a current flows through elements such as the SBD, a field-plate insulating material layer 3 disposed between the n-type gallium oxide epitaxial layer 6 and an anode electrode 1. A laminated portion of the field-plate insulating material layer 3 and the anode electrode 1 forms a field plate structure. This increases the breakdown voltage of the semiconductor device when a reverse voltage is applied to the semiconductor device.

Furthermore, a cathode electrode 8 that is an electrode that forms an electrical Ohmic junction with the lower surface of the n-type single-crystal gallium oxide substrate 7 is formed on the lower surface of the n-type single-crystal gallium oxide substrate 7.

Next, the aforementioned constituent elements will be further described in detail.

The n-type single-crystal gallium oxide substrate 7 is an n-type oxide semiconductor made of a single crystal of Ga₂O₃, and is preferably an n-type oxide semiconductor made of a single crystal of β-Ga₂O₃. Using the single crystal of Ga₂O₃ in the n-type single-crystal gallium oxide substrate 7 can produce the n-type single-crystal gallium oxide substrate 7 with a stable crystalline structure and stable physical properties.

Since the n-type single-crystal gallium oxide substrate 7 exhibits n-type conductivity from oxygen deficiency in crystals, it does not have to contain n-type impurities. The n-type single-crystal gallium oxide substrate 7 may contain n-type impurities such as silicon (Si) or tin (Sn). In other words, the n-type single-crystal gallium oxide substrate 7 may be any of the following substrates: a substrate that exhibits n-type conductivity solely from oxygen deficiency; a substrate that exhibits n-type conductivity solely from n-type impurities; and a substrate that exhibits n-type conductivity from both of oxygen deficiency and n-type impurities.

The n-type carrier concentration (electron carrier concentration) of the n-type single-crystal gallium oxide substrate 7 containing n-type impurities is a total density of oxygen deficiency and n-type impurities. The n-type carrier concentration (electron carrier concentration) of the n-type single-crystal gallium oxide substrate 7 may be, for example, 1×10¹⁷ cm⁻³ or higher and 1×10¹⁹ cm⁻³ or lower. The impurity concentration may be a concentration higher than the aforementioned numerical range to reduce contact resistance between the n-type single-crystal gallium oxide substrate 7 and the cathode electrode 8.

The n-type gallium oxide epitaxial layer 6 is formed on the upper surface of the n-type single-crystal gallium oxide substrate 7. The n-type gallium oxide epitaxial layer 6 is an n-type oxide semiconductor made of the single crystal of Ga₂O₃, and is preferably an n-type oxide semiconductor made of the single crystal of β-Ga₂O₃. Using the single crystal of β-Ga₂O₃ in the n-type gallium oxide epitaxial layer 6 can produce the n-type gallium oxide epitaxial layer 6 with a stable crystalline structure and stable physical properties.

Preferably, the n-type carrier concentration (electron carrier concentration) of the n-type gallium oxide epitaxial layer 6 may be a concentration lower than the electron carrier concentration of the n-type single-crystal gallium oxide substrate 7, for example, 1×10¹⁵ cm⁻³ or higher and 1×10¹⁷ cm⁻³ or lower.

The trench structure 100 is formed in the surface layer of the n-type gallium oxide epitaxial layer 6. A method for forming the trench structure 100 is not particularly limited but may be formed by dry etching using, for example, BCl₃ gas.

When the trench structure 100 is formed, the anode electrodes 2 that form a Schottky junction with the n-type gallium oxide epitaxial layer 6 can be used as an etching mask. It is preferred to prevent deterioration of the surface of the anode electrodes 2 from etching. Schottky electrodes may be made of, for example, platinum (Pt), nickel (Ni), gold (Au), or palladium (Pd). When etching causes significant deterioration in a material, the anode electrodes 2 may particularly have a laminated structure.

For example, the anode electrodes 2 with a laminated structure are preferably formed by forming, in contact with the n-type gallium oxide epitaxial layer 6, a first layer made of a metal suitable for the Schottky junction with the n-type gallium oxide epitaxial layer 6 and forming, on an upper surface of the first layer, a second layer made of another metal with better etching resistance.

The cathode electrode 8 is formed on the lower surface of the n-type single-crystal gallium oxide substrate 7. Since the cathode electrode 8 forms an Ohmic junction with the n-type single-crystal gallium oxide substrate 7, the cathode electrode 8 is preferably made of a metal whose work function is smaller than that of the n-type single-crystal gallium oxide substrate 7. Furthermore, the cathode electrode 8 is preferably made of a metal that reduces contact resistance between the n-type single-crystal gallium oxide substrate 7 and the cathode electrode 8 through heat treatment performed after forming the cathode electrode 8 on the lower surface of the n-type single-crystal gallium oxide substrate 7. Such metal may be, for example, titanium (Ti).

Furthermore, the cathode electrode 8 may be formed by laminating a plurality of metals. For example, when a metal prone to oxidation is in contact with the lower surface of the n-type single-crystal gallium oxide substrate 7, further forming a metal resistant to oxidation on the lower surface of the metal prone to oxidation may produce the cathode electrode 8 with a laminated structure. For example, the cathode electrode 8 with the laminated structure may be formed by forming, in contact with the n-type single-crystal gallium oxide substrate 7, a first layer made of Ti and forming, on a lower surface of the first layer, a second layer made of gold (Au) or silver (Ag).

The cathode electrode 8 may be formed on the entire lower surface or a part of the lower surface of the n-type single-crystal gallium oxide substrate 7.

The anode electrode 1 is formed above the n-type gallium oxide epitaxial layer 6. The p-type semiconductor layer 5 is formed between the anode electrode 1 and the n-type gallium oxide epitaxial layer 6, and the anode electrode 1 preferably forms an Ohmic junction with the p-type semiconductor layer 5. Thus, the anode electrode 1 is preferably made of a metal whose work function is smaller than that of the p-type semiconductor layer 5. Such metal may be, for example, Au.

The anode electrode 1 may have a laminated structure similarly to the anode electrodes 2 or the cathode electrode 8. For example, the anode electrode 1 with a laminated structure may be formed by forming, in contact with the p-type semiconductor layer 5, a first layer made of a metal suitable for the Ohmic junction with the p-type semiconductor layer 5 and forming, on an upper surface of the first layer, a second layer made of another metal.

The p-type semiconductor layer 5 is also formed in an inner portion of the trench structure 100 formed in the surface layer of the n-type gallium oxide epitaxial layer 6. Furthermore, the p-type semiconductor layer 5 is formed to cover the external portion (i.e., a top) of the trench structure 100 through the anode electrodes 2.

The material of the p-type semiconductor layer 5 is not particularly limited, but preferably a p-type oxide semiconductor material. The p-type semiconductor layer 5 is preferably made of a p-type oxide semiconductor exhibiting p-type conductivity without being doped with p-type impurities, such as copper oxide (Cu₂O), silver oxide (Ag₂O), nickel oxide (NiO), or tin oxide (SnO). For example, Cu₂O, which is metal oxide, exhibits p-type conductivity because the 3d orbital of Cu forms the valence band maximum that undertakes hole conduction, and holes appear due to Cu deficiency. When Cu₂O transforms into CuO due to oxidation, the 3d orbital of Cu does not form the valence band maximum, and the p-type conductivity is lost. The p-type semiconductor layer 5 is preferably made of a p-type oxide semiconductor including metal oxide with such properties. The p-type oxide semiconductor such as Cu₂O typically exhibits p-type conductivity without being doped with p-type impurities.

When the p-type semiconductor layer 5 consists of a p-type oxide semiconductor, the p-type semiconductor layer 5 is made of the p-type oxide semiconductor exhibiting p-type conductivity without being doped with p-type impurities as described above. Even in such a case, p-type impurities may be added. For example, when the p-type semiconductor layer 5 is made of Cu₂O, nitrogen (N) may be used as p-type impurities.

When the p-type semiconductor layer 5 is not doped with p-type impurities, the p-type carrier density (electron carrier concentration) of the p-type semiconductor layer 5 is a density of metal atom deficiency in the p-type oxide semiconductor. When the p-type semiconductor layer 5 is doped with p-type impurities, the p-type carrier density is a total density of the metal atom deficiency in the p-type oxide semiconductor and the p-type impurities. When the p-type semiconductor layer 5 is doped with p-type impurities, even after the metal oxide of the p-type oxide semiconductor is oxidized and loses p-type conductivity, the entire p-type oxide semiconductor sometimes exhibits the p-type conductivity with the p-type impurities. When the metal oxide of the p-type oxide semiconductor is oxidized and loses the p-type conductivity corresponding to the oxidation, the p-type conductivity of the entire p-type oxide semiconductor decreases. Thus, it is preferred not to oxidize the metal oxide of the p-type oxide semiconductor.

The field-plate insulating material layer 3 is made of a material, for example, silicon dioxide (SiO₂) or aluminum oxide (Al₂O₃). These materials have breakdown field strength higher than that of Ga₂O₃ contained in the n-type gallium oxide epitaxial layer 6. The thickness of the field-plate insulating material layer 3 may be 1 μm or less, for example, 200 nm or more and 900 nm or less, which differs depending on a structure of a device.

Furthermore, the field-plate insulating material layer 3 of which example is illustrated in FIG. 1 does not have a simple one-layer structure but has a multiple stepped field plate structure formed stepwise. Specifically, the field-plate insulating material layer 3 is formed across the upper surfaces of the p-type semiconductor layer 5 and the n-type gallium oxide epitaxial layer 6. Since the field-plate insulating material layer 3 is formed with a portion of the p-type semiconductor layer 5 on the top of the trench structure 100 (i.e., a portion formed on the upper surface of the n-type gallium oxide epitaxial layer 6 through the anode electrodes 2), a portion of the p-type semiconductor layer 5 on the upper surface of the n-type gallium oxide epitaxial layer 6 outside the trench structure 100, and an inner portion of the trench structure 100. Thus, the field-plate insulating material layer 3 has the multiple stepped structure. Thus, the field-plate insulating material layer 3 is preferably shaped like a slope or a step. When the field-plate insulating material layer 3 is shaped like a slope or a step, the field strength at an electric field concentration point of a device can be suppressed. Thus, it is possible to expect an increase in the breakdown voltage of the device.

### Method for Manufacturing Semiconductor Device

Next, a method for manufacturing an oxide semiconductor device as a semiconductor device according to Embodiment 1 will be described with reference to FIGS. 1 to 8. FIGS. 2 to 8 are cross-sectional views illustrating the method for manufacturing the semiconductor device according to Embodiment 1.

First, the n-type single-crystal gallium oxide substrate 7 is prepared as the example illustrated in FIG. 2. A substrate obtained by cutting, into substrates, a single-crystal bulk made of β-Ca₂O₃ produced by a melt growth process can be used as the n-type single-crystal gallium oxide substrate 7.

Next, the n-type gallium oxide epitaxial layer 6 is deposited on the upper surface of the n-type single-crystal gallium oxide substrate 7 through epitaxial growth as the example illustrated in FIG. 3. The method for forming the n-type gallium oxide epitaxial layer 6 is not particularly limited. For example, the n-type gallium oxide epitaxial layer 6 can be formed on the upper surface of the n-type single-crystal gallium oxide substrate 7 by a method such as metal organic chemical vapor deposition (i.e., MOCVD), molecular beam epitaxy (i.e., MBE), or halide vapor phase epitaxy (i.e., HVPE).

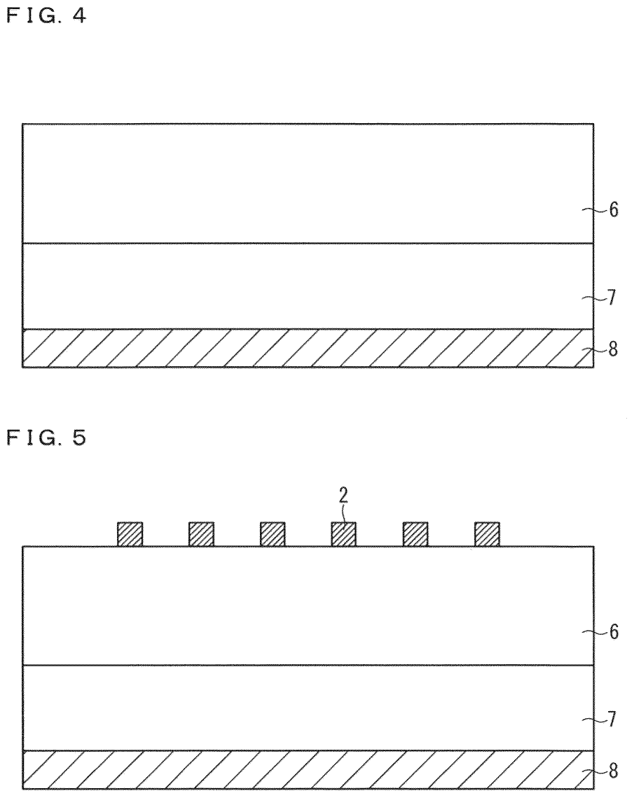

Next, a metal to be the cathode electrode 8 is deposited by vapor deposition or sputtering on the lower surface of the n-type single-crystal gallium oxide substrate 7 as the example illustrated in FIG. 4. For example, a Ti layer of a thickness of 50 nm is deposited on the lower surface of the n-type single-crystal gallium oxide substrate 7 by electron beam evaporation (EB evaporation). Then, an Au layer of a thickness of 300 nm is deposited on the Ti layer by electron beam evaporation to form the cathode electrode 8 having a two-layer structure. Thereafter, for example, heat treatment is performed at 550°° C. for five minutes under a nitrogen atmosphere or an oxygen atmosphere. As a result, the cathode electrode 8 that forms an Ohmic junction with the n-type single-crystal gallium oxide substrate 7 is formed on the lower surface of the n-type single-crystal gallium oxide substrate 7. To reduce contact resistance between the n-type single-crystal gallium oxide substrate 7 and the cathode electrode 8, an RIE process using gas such as BCl₃ may be performed on the lower surface of the n-type single-crystal gallium oxide substrate 7 before forming the cathode electrode 8.

Next, the anode electrodes 2 are formed on a part of the upper surface of the n-type gallium oxide epitaxial layer 6 in the active region enclosed by the termination structure in a plan view as the example illustrated in FIG. 5. The anode electrodes 2 are formed at positions without overlapping the trench structure 100 to be formed in a latter process in a plan view. The method for forming the anode electrodes 2 is not particularly limited. For example, after forming a resist pattern mask by photolithography and forming a metal that forms a Schottky junction with the n-type gallium oxide epitaxial layer 6, the anode electrodes 2 can be formed through a lift-off process.

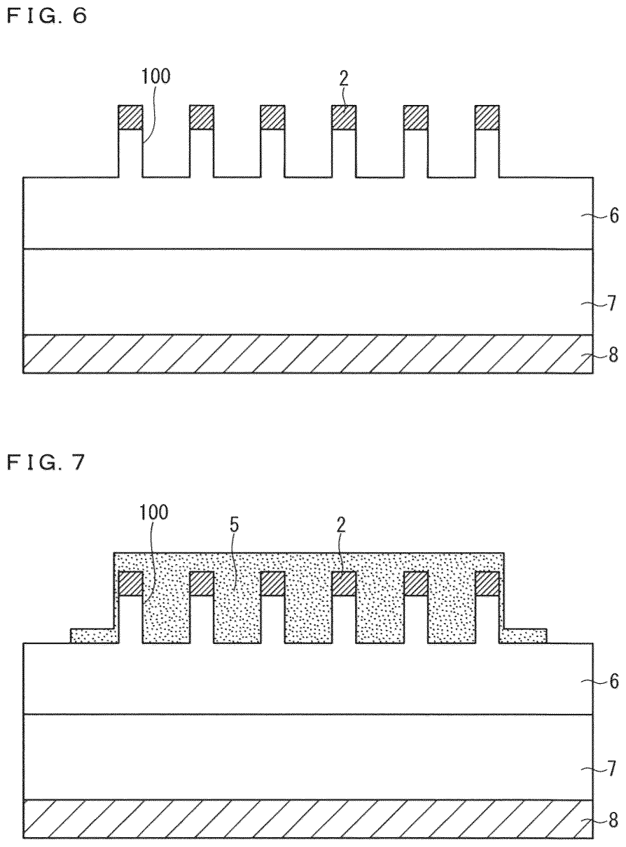

Next, the trench structure 100 is formed using the anode electrodes 2 as an etching mask as the example illustrated in FIG. 6. The trench structure 100 is formed by dry etching using, for example, dry etching gas such as boron trichloride (BCl₃) in the surface layer of the n-type gallium oxide epitaxial layer 6. The method for forming the trench structure 100 is not particularly limited but can be an existing formation method such as dry etching or wet etching. Furthermore, a damaged layer formed by etching on the n-type gallium oxide epitaxial layer 6 is preferably removed in a latter process.

Next, the p-type semiconductor layer 5 is formed to cover an inner portion of the trench structure 100 and an external portion of the trench structure 100 (i.e., the top of the trench structure 100 in which the anode electrodes 2 are formed and an exposed portion including a part of the upper surface of the n-type gallium oxide epitaxial layer 6 where the anode electrodes 2 are not formed) as the example illustrated in FIG. 7. The method for forming the p-type semiconductor layer 5 is not particularly limited but includes a method for forming the p-type semiconductor layer 5 with desired physical properties, using a method such as sputtering or pulse laser deposition (i.e., PLD). Furthermore, patterns can be formed by various methods, such as formation by lift-off or etching.

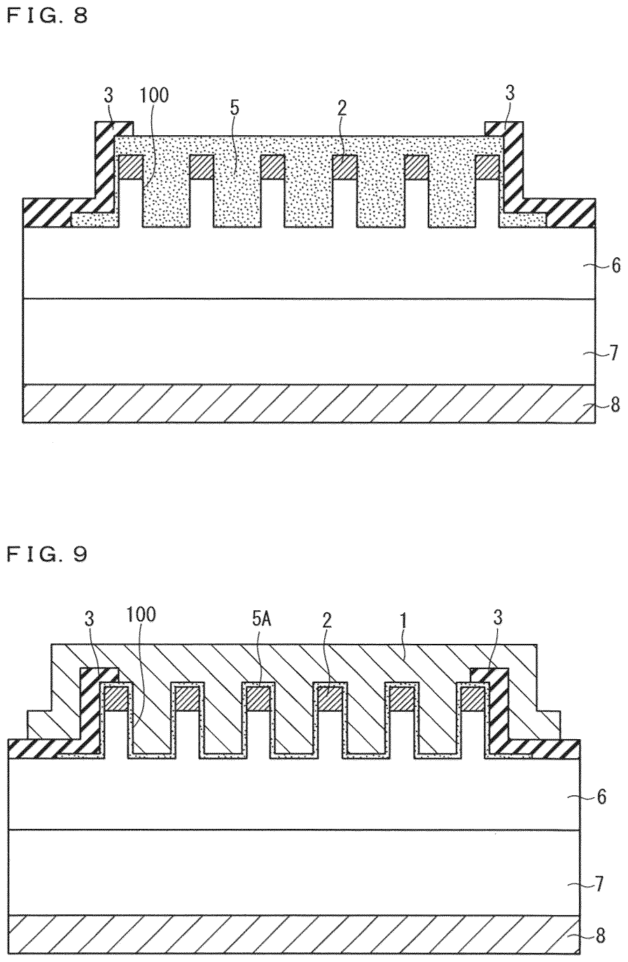

Next, the field-plate insulating material layer 3 is formed on the exposed upper surface of the n-type gallium oxide epitaxial layer 6 and the upper surface of the p-type semiconductor layer 5 in the termination structure as the example illustrated in FIG. 8. The method for forming the field-plate insulating material layer 3 is not particularly limited. For example, the field-plate insulating material layer 3 can be formed by plasma CVD, sputtering, or spin-on glass (i.e., SOG).

Finally, forming the anode electrode 1 on the upper surface of the p-type semiconductor layer 5 and the upper surface of the field-plate insulating material layer 3 completes the semiconductor device according to Embodiment 1 as the example illustrated in FIG. 1.

### Embodiment 2

A semiconductor device, and a method for manufacturing the semiconductor device according to Embodiment 2 will be described. In the following description, the same reference numerals are assigned to the same constituent elements as those described in Embodiment 1, and the detailed description will be appropriately omitted.

### Structure of Semiconductor Device

FIG. 9 is a cross-sectional view schematically illustrating an example structure of the semiconductor device according to Embodiment 2. The method for manufacturing the semiconductor device according to Embodiment 2 is identical to that according to Embodiment 1.

The p-type semiconductor layer 5 is formed to fill the inner portion of the trench structure 100 in the semiconductor device in FIG. 1. In contrast, a p-type semiconductor layer 5A is formed on sidewalls and at a bottom of the trench structure 100 in the semiconductor device according to Embodiment 2 in FIG. 9. The p-type semiconductor layer 5A is formed at the bottom and on the side surface of the inner portion of the trench structure 100 without filling the inner portion of the trench structure 100. Then, the anode electrode 1 enclosed by the p-type semiconductor layer 5A in the inner portion of the trench structure 100 is formed.

A p-type semiconductor layer sometimes functions as a resistance component of a device. Inclusion of the p-type semiconductor layer 5A as illustrated in FIG. 9 can implement a semiconductor device with a low resistance.

### Method for Manufacturing Semiconductor Device

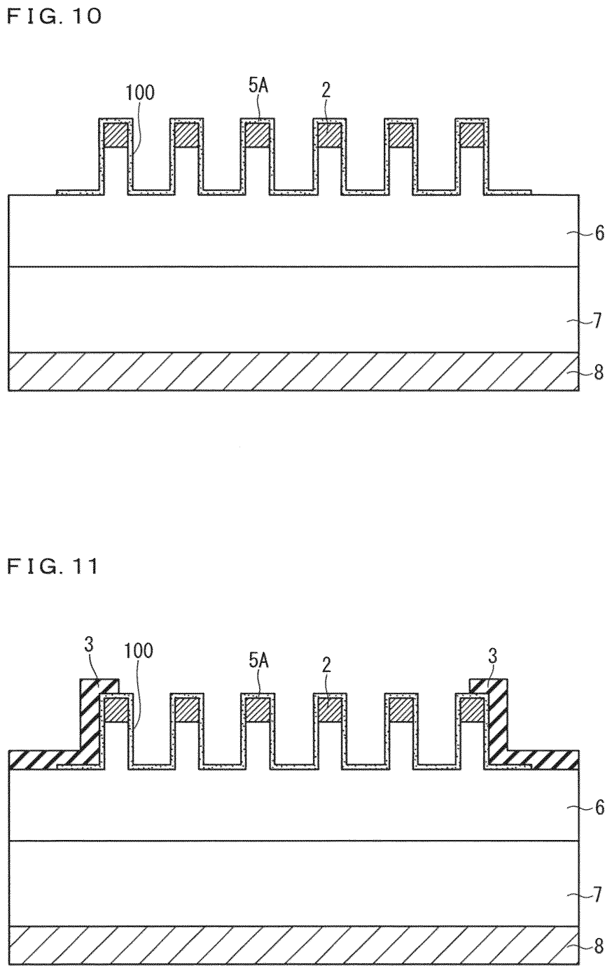

Next, a method for manufacturing an oxide semiconductor device as a semiconductor device according to Embodiment 2 will be described with reference to FIGS. 9 to 11. FIGS. 10 and 11 are cross-sectional views illustrating the method for manufacturing the semiconductor device according to Embodiment 2.

First, as the example illustrated in FIG. 10, the p-type semiconductor layer 5A is formed in the structure illustrated in FIG. 6 to cover an inner portion of the trench structure 100 and an external portion of the trench structure 100 (i.e., the top of the trench structure 100 in which the anode electrodes 2 are formed, and an exposed portion including a part of the upper surface of the n-type gallium oxide epitaxial layer 6 where the anode electrodes 2 are not formed). The method for forming the p-type semiconductor layer 5A is not particularly limited but includes a method for forming the p-type semiconductor layer 5A with desired physical properties, using a method such as sputtering or PLD.

Next, the field-plate insulating material layer 3 is formed on the exposed upper surface of the n-type gallium oxide epitaxial layer 6 and the upper surface of the p-type semiconductor layer 5A in the termination structure as the example illustrated in FIG. 11. The method for forming the field-plate insulating material layer 3 is not particularly limited. For example, the field-plate insulating material layer 3 can be formed by plasma CVD, sputtering, or SOG.

Finally, forming the anode electrode 1 on the upper surface of the p-type semiconductor layer 5A and the upper surface of the field-plate insulating material layer 3 completes the semiconductor device according to Embodiment 2 as the example illustrated in FIG. 9.

### Embodiment 3

A semiconductor device, and a method for manufacturing the semiconductor device according to Embodiment 3 will be described. In the following description, the same reference numerals are assigned to the same constituent elements as those described in Embodiments 1 and 2, and the detailed description will be appropriately omitted.

### Structure of Semiconductor Device

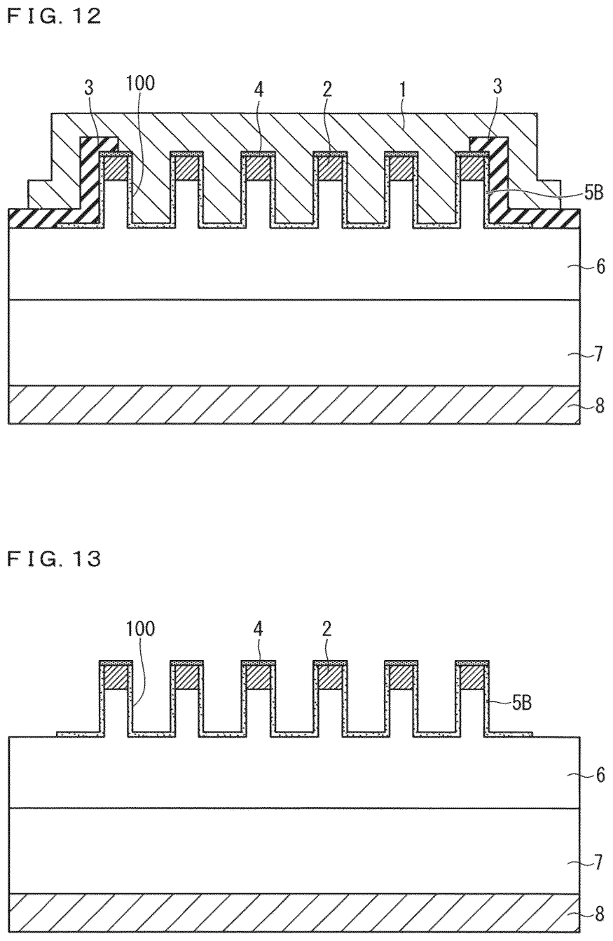

FIG. 12 is a cross-sectional view schematically exemplifying a structure of a semiconductor device according to Embodiment 3. The method for manufacturing the semiconductor device according to Embodiment 3 is almost identical to those according to Embodiments 1 and 2.

The p-type semiconductor layer 5A is also formed on the top of the trench structure 100 in the active region in the semiconductor device in FIG. 9. In contrast, in the semiconductor device according to Embodiment 3 in FIG. 12, a p-type altered layer 4 is formed on the top of the trench structure 100 in the active region to cover the upper surface of the anode electrodes 2.

The p-type altered layer 4 is a layer lower in electrical resistance than the p-type semiconductor layer 5A. When the p-type semiconductor layer 5A is, for example, an oxide semiconductor, the p-type altered layer 4 is preferably the oxide semiconductor that is reduced and metallized (achieves a lower resistance). A p-type semiconductor layer 5B is formed on portions in which the p-type altered layer 4 is not formed (except the top of the external portion of the trench structure 100, the inner portion of the trench structure 100, and the side surface of the anode electrodes 2). The p-type altered layer 4 is lower in electrical resistance than the p-type semiconductor layer 5A.

The method for forming the p-type altered layer 4 is not particularly limited. For example, the p-type semiconductor layer 5A can be altered to a low resistance layer (i.e., the p-type altered layer 4) by plasma treatment. Here, gases including helium, argon, hydrogen, nitrogen, and oxygen can be used in the plasma treatment. The p-type altered layer 4 contains at least one type of helium, argon, hydrogen, nitrogen, or oxygen which are derived from these gases.

Forming the p-type altered layer 4 on the upper surface of the external portion of the trench structure 100 in the active region reduces the resistance between the anode electrode 1 and the anode electrodes 2. Thus, the resistance of the semiconductor device itself can be reduced. Since the p-type semiconductor layer 5 can be altered to the p-type altered layer 4 through the plasma treatment using argon gas, the resistance of a material having high etching resistance and having difficulty in being processed can be reduced.

### Method for Manufacturing Semiconductor Device

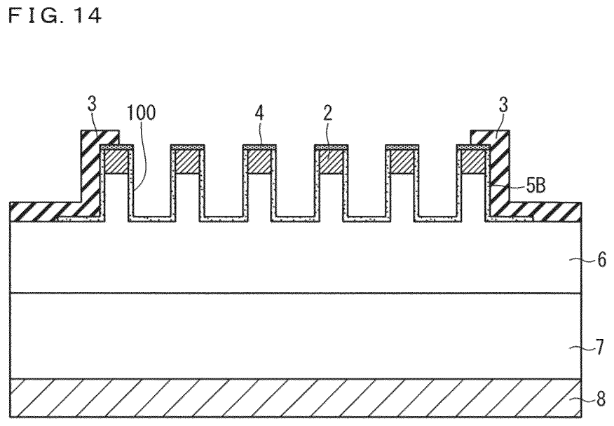

Next, a method for manufacturing an oxide semiconductor device as a semiconductor device according to Embodiment 3 will be described with reference to FIGS. 12 to 14. FIGS. 13 and 14 are cross-sectional views illustrating the method for manufacturing the semiconductor device according to Embodiment 3.

First, the top of the trench structure 100 on which the anode electrodes 2 are formed in the structure of FIG. 10 is irradiated with plasma as the example illustrated in FIG. 13. This alters the p-type semiconductor layer 5A formed on the upper surface of the anode electrodes 2 to form the p-type altered layer 4.

Next, the field-plate insulating material layer 3 is formed on a part of the upper surface of the p-type altered layer 4, the exposed upper surface of the n-type gallium oxide epitaxial layer 6, and the upper surface of the p-type semiconductor layer 5B in the termination structure as the example illustrated in FIG. 14. The method for forming the field-plate insulating material layer 3 is not particularly limited. For example, the field-plate insulating material layer 3 can be formed by plasma CVD, sputtering, or SOG.

Finally, forming the anode electrode 1 on the upper surface of the p-type altered layer 4, the upper surface of the p-type semiconductor layer 5A, and the upper surface of the field-plate insulating material layer 3 completes the semiconductor device according to Embodiment 3 as the example illustrated in FIG. 12.

### Advantages Produced by Embodiments Above

Next, example advantages produced by Embodiments above will be described. Although the advantages will be described based on the specific structures whose examples are shown in Embodiments above, the structures may be replaced with another specific structure whose example is shown in this DESCRIPTION as long as it produces the same advantages. Specifically, although only one of the corresponding specific structures is sometimes described as a representative for convenience, the structure may be replaced with another specific structure associated with the structure described as the representative.

The replacement may be performed across a plurality of Embodiments. Specifically, the replacement may be performed when combinations of the structures whose examples are described in different Embodiments produce the same advantages.

A semiconductor device according to Embodiments above includes a gallium oxide layer of a first conductivity type, a first anode electrode, a semiconductor layer of a second conductivity type, and a second anode electrode. Here, the gallium oxide layer corresponds to, for example, the n-type gallium oxide epitaxial layer 6. The first anode electrode corresponds to, for example, the anode electrode 2. Furthermore, the semiconductor layer corresponds to, for example, the p-type semiconductor layer 5, 5A, or 5B. The second anode electrode corresponds to, for example, the anode electrode 1. The anode electrodes 2 are formed in a part of the upper surface of the n-type gallium oxide epitaxial layer 6. The p-type semiconductor layer 5 is formed to cover a part of the n-type gallium oxide epitaxial layer 6 and at least a part of the anode electrodes 2. The anode electrode 1 is formed to cover the p-type semiconductor layer 5. Furthermore, a plurality of trenches is formed in the surface layer of the n-type gallium oxide epitaxial layer 6. Here, the trenches correspond to, for example, the trench structure 100. The anode electrodes 2 are formed in the surface layer of the n-type gallium oxide epitaxial layer 6 that does not overlap the trench structure 100 in a plan view. The p-type semiconductor layer 5 is formed to cover the n-type gallium oxide epitaxial layer 6 in the inner portion of the trench structure 100.

Such a structure can suppress the leakage current. Specifically, forming the anode electrodes 2 in the top of the trench structure 100 produces a structure in which the anode electrodes 2 protect the Schottky junction formed between the lower surface of the anode electrodes 2 and the top of the trench structure 100. Thus, the Schottky junction formed between the lower surface of the anode electrodes 2 and the top of the trench structure 100 is not damaged in a manufacturing process after forming the structure. This can suppress an increase in the leakage current due to the damaged Schottky junction.

When the other structures whose examples are described in DESCRIPTION are appropriately added, that is, the other structures in DESCRIPTION which are not mentioned as the structure above are appropriately added, the same advantages can be produced.

The p-type semiconductor layer 5A (p-type semiconductor layer 5B) is formed at a bottom and on a side surface of the inner portion of the trench structure 100 according to Embodiments above. The anode electrode 1 enclosed by the p-type semiconductor layer 5A (p-type semiconductor layer 5B) in the inner portion of the trench structure 100 is formed. Such a structure can reduce an element resistance more than that when the entire inner portion of the trench structure 100 is filled with a p-type semiconductor layer.

The p-type semiconductor layer 5 is made of metal oxide according to Embodiments above. Such a structure enables the p-type semiconductor layer 5 to exhibit p-type conductivity without being doped with p-type impurities. The hetero p-n junction between the p-type semiconductor layer 5 and the n-type gallium oxide epitaxial layer 6 is formed by oxides, which improves the stability.

The metal oxide is copper oxide, silver oxide, nickel oxide, or tin oxide according to Embodiments above. Such a structure enables the p-type semiconductor layer 5 to exhibit p-type conductivity without being doped with p-type impurities. The hetero p-n junction between the p-type semiconductor layer 5 and the n-type gallium oxide epitaxial layer 6 is formed by oxides, which improves the stability.

The semiconductor device according to Embodiments above includes an altered layer of the second conductivity type formed to cover the upper surface of the anode electrodes 2. Here, the altered layer corresponds to, for example, the p-type altered layer 4. The p-type semiconductor layer 5B is formed to cover the side surface of the anode electrodes 2. The p-type altered layer 4 is lower in electrical resistance than the p-type semiconductor layer 5B. Irradiating, with plasma, a part of the p-type semiconductor layer 5B integrally formed may alter the part to the p-type altered layer 4. Alternatively, the p-type semiconductor layer 5B and the p-type altered layer 4 may be independently/separately formed. Since such a structure can reduce the electrical resistance between the anode electrodes 2 and the anode electrode 1, the ON resistance of a device can be reduced.

Furthermore, the p-type altered layer 4 contains at least one of helium, argon, hydrogen, nitrogen, or oxygen according to Embodiments above. Such a structure forms the p-type altered layer 4 from the p-type semiconductor layer through plasma irradiation using at least one of helium, argon, hydrogen, nitrogen, or oxygen. Thereby, the resistance of a material having high etching resistance (and having difficulty in being processed) can be reduced.

The anode electrodes 2 are formed in a part of the upper surface of the n-type gallium oxide epitaxial layer 6 of the first conductivity type in the method for manufacturing the semiconductor device according to Embodiments above. Then, etching the surface layer of the n-type gallium oxide epitaxial layer 6 using the anode electrodes 2 as a mask produces a plurality of the trench structures 100. Then, the p-type semiconductor layer 5 of the second conductivity type is formed to cover a part of the n-type gallium oxide epitaxial layer 6 including the inner portion of the trench structure 100, and at least a part of the anode electrodes 2. Then, the anode electrode 1 is formed to cover the p-type semiconductor layer 5.

Such a structure can suppress the leakage current. Forming the trench structure 100 using the anode electrodes 2 as an etching mask and forming the p-type semiconductor layer 5 to cover an inner portion and an external portion of the trench structure 100 while maintaining the anode electrodes 2 can easily manufacture a JBS element without removing the p-type semiconductor layer 5 (without any process such as planarizing). Since processing the p-type semiconductor layer 5 is unnecessary, damage to the p-type semiconductor layer 5 which occurs in the process can be suppressed, and the stability of a Schottky interface can be improved.

When there is no particular limitation, the order of processes can be changed.

When the other structures whose examples are described in DESCRIPTION are appropriately added, that is, the other structures in DESCRIPTION which are not mentioned as the structure above are appropriately added, the same advantages can be produced.

The method for manufacturing the semiconductor device according to Embodiments above includes forming the altered layer 4 of the second conductivity type to cover the upper surface of the anode electrodes 2. Here, the p-type semiconductor layer 5B is formed to cover the side surface of the anode electrodes 2. The p-type altered layer 4 is lower in electrical resistance than the p-type semiconductor layer 5B. Since such a structure can reduce the electrical resistance between the anode electrodes 2 and the anode electrode 1, the resistance of a device can be reduced.

Furthermore, irradiating the p-type semiconductor layer 5A covering the upper surface of the anode electrodes 2 with plasma forms the p-type altered layer 4 according to Embodiments above. Such a structure forms the p-type altered layer 4 from the p-type semiconductor layer through plasma irradiation using at least one of helium, argon, hydrogen, nitrogen, or oxygen. Thereby, the resistance of a material having high etching resistance (and having difficulty in being processed) can be reduced.

### Modifications of Embodiments Above

Although Embodiments described above sometimes specify, for example, properties of materials, the materials, dimensions, shapes, relative arrangement relationships, and conditions for implementing each of the constituent elements, these are examples in all aspects and are not restrictive.

Therefore, numerous modifications and equivalents that have not yet been exemplified are devised within the scope of the technology disclosed in DESCRIPTION. Examples of the modifications include modifying, adding, or omitting at least one constituent element, and further extracting at least one constituent element in at least one of Embodiments and combining the extracted constituent element with a constituent element in another Embodiment.

When at least one of Embodiments above specifies, for example, the name of a material without any particular designation, the material includes another additive, for example, an alloy unless it is contradictory.

Furthermore, when a constituent element is described as one element in Embodiments above, the number of the constituent elements may be more than one unless it is contradictory.

Furthermore, the constituent elements according to Embodiments above are conceptual units, and the scope of the technology disclosed in DESCRIPTION covers one constituent element comprising a plurality of structures, one constituent element corresponding to a part of a structure, and a plurality of constituent elements included in one structure.

Furthermore, each of the constituent elements in Embodiments above includes another structure or a structure having a shape as long as it exercises the same function.

Furthermore, the description is referred to for all the objectives relating to the present technology, and is not regarded as prior art.

### EXPLANATION OF REFERENCE SIGNS

1 anode electrode, 2 anode electrode.

1. A semiconductor device, comprising:
a gallium oxide layer of a first conductivity type;
a first anode electrode formed in a part of an upper surface of the gallium oxide layer;
a semiconductor layer of a second conductivity type to cover a part of the gallium oxide layer and at least a part of the first anode electrode; and
a second anode electrode to cover the semiconductor layer,
wherein a plurality of trenches is formed in a surface layer of the gallium oxide layer,
the first anode electrode is formed in the surface layer of the gallium oxide layer, the first anode electrode not overlapping the trenches in a plan view, and
the semiconductor layer covers the gallium oxide layer in an inner portion of the trenches.

2. The semiconductor device according to claim 1,
wherein the semiconductor layer is formed at a bottom and on a side surface of the inner portion of the trenches, and
the second anode electrode is enclosed by the semiconductor layer in the inner portion of the trenches.

3. The semiconductor device according to claim 1,
wherein the semiconductor layer is made of metal oxide.

4. The semiconductor device according to claim 3,
wherein the metal oxide is copper oxide, silver oxide, nickel oxide, or tin oxide.

5. The semiconductor device according to claim 1, further comprising
an altered layer of the second conductivity type to cover an upper surface of the first anode electrode,
wherein the semiconductor layer is formed to cover a side surface of the first anode electrode, and
the altered layer is lower in electrical resistance than the semiconductor layer.

6. The semiconductor device according to claim 5,
wherein the altered layer contains at least one of helium, argon, hydrogen, nitrogen, or oxygen.

7. A method for manufacturing a semiconductor device, the method comprising:
forming a first anode electrode in a part of an upper surface of a gallium oxide layer of a first conductivity type;
etching a surface layer of the gallium oxide layer using the first anode electrode as a mask to form a plurality of trenches;
forming a semiconductor layer of a second conductivity type to cover a part of the gallium oxide layer including an inner portion of the trenches, and at least a part of the first anode electrode; and
forming a second anode electrode to cover the semiconductor layer.

8. The method according to claim 7, further comprising
forming an altered layer of the second conductivity type to cover an upper surface of the first anode electrode,
wherein the semiconductor layer is formed to cover a side surface of the first anode electrode, and
the altered layer is lower in electrical resistance than the semiconductor layer.

9. The method according to claim 8, comprising
irradiating the semiconductor layer with plasma to form the altered layer, the semiconductor layer covering the upper surface of the first anode electrode.

10. The semiconductor device according to claim 2,
wherein the semiconductor layer is made of metal oxide.

11. The semiconductor device according to claim 2, further comprising
an altered layer of the second conductivity type to cover an upper surface of the first anode electrode,
wherein the semiconductor layer is formed to cover a side surface of the first anode electrode, and
the altered layer is lower in electrical resistance than the semiconductor layer.

12. The semiconductor device according to claim 3, further comprising
an altered layer of the second conductivity type to cover an upper surface of the first anode electrode,
wherein the semiconductor layer is formed to cover a side surface of the first anode electrode, and
the altered layer is lower in electrical resistance than the semiconductor layer.

13. The semiconductor device according to claim 4, further comprising
an altered layer of the second conductivity type to cover an upper surface of the first anode electrode,
wherein the semiconductor layer is formed to cover a side surface of the first anode electrode, and
the altered layer is lower in electrical resistance than the semiconductor layer.
